(19) United States
(12) Patent Application Publication
(10) Pub. No.: US 2014/0117005 A1
(43) Pub. Date: May 1, 2014

(54) DIFFUSION FURNACE

(71) Applicant: TANGTECK EQUIPMENT INC., Taoyuan County (TW)

(72) Inventors: MING-HUI YU, TAIPEI CITY (TW); CHIA-JUNG KAO, TAIPEI CITY (TW); A-TZU CHEN, NEW TAIPEI CITY (TW); WANG-TSUNG LIANG, TAOYUAN COUNTY (TW); CHANG-FA CHEN, Taoyuan County (TW)

(73) Assignee: TANGTECK EQUIPMENT INC., Taoyuan County (TW)

(21) Appl. No.: 14/148,214

(22) Filed: Jan. 6, 2014

Related U.S. Application Data
(63) Continuation-in-part of application No. 13/231,923, filed on Sep. 13, 2011.

(30) Foreign Application Priority Data
Oct. 27, 2011 (TW) 99220775

(51) Int. Cl. H01L 21/67

(52) U.S. Cl. CPC H01L 21/67098
USPC 219/395; 219/408; 219/410

(57) ABSTRACT

A diffusion furnace in the shape of polygonal-prism, including two end frame plates arranged in opposite basal planes of the diffusion furnace and a plurality of heating panels connected between the two end frame plates. Each heating panel includes at least one beam connected between the two end frame plates and a plurality of heating block interconnected in succession along and secured to the respective beam. Each heating block includes a block body, at least one heating element arranged on one side of the block body and amounting assembly mounted on the opposite side of the block body for securing the heating element. Thus, the disclosed diffusion furnace can be customized to satisfy different measurements requirement and can be easily decomposed for repair.

### CROSS REFERENCE TO RELATED APPLICATION

This application is a continuation-in-part (CIP) of co-pending application Ser. No. 13/231,923, filed on Sep. 13, 2011 the entire contents of which are hereby incorporated by reference and for which priority is claimed under 35 U.S.C. §120.

### BACKGROUND OF THE INVENTION

1. Field of the Invention

The instant disclosure relates to a modularized diffusion furnace; more particularly, to a diffusion furnace formed by multiple heating panels assembled from a plurality of modularized heating blocks, whose modularized design offers higher degrees of operational flexibility in terms of dimension configuration, as well as enabling easier disassembly and thus more efficient maintenance.

2. Description of Related Art

Diffusion furnace is an essential piece of equipment in the manufacturing/fabrication process of various sophisticated modern semiconductor devices, including solar cells. For example, the fabrication of CIGS (copper indium gallium selenide) thin-film solar cell (TFSC) involves the following procedures. First, a molybdenum layer (Mo), serving as a back contact, will be coated on a substrate (such as glass, stainless steel, etc.). Then, a CIGS precursor film of corresponding thickness is formed on the molybdenum layer. The deposition of copper (Cu), indium (In), and gallium (Ga) film can be done by methods including physical vapor deposition (PVD), electro-less plating, and electroplating. Then, the substrate having a film that comprises copper, indium, and gallium is placed in a diffusion furnace with selenide vapor introduced therein and undergoes an annealing process under high temperature condition (typically between 500˜600 degree Celsius) to form the final CIGS thin film.

In practical application, the appropriate dimension of the diffusion furnace is preferably chosen in accordance to the size of the target subject to be processed, e.g., the size of the thin-film solar cell, as a furnace having overly small dimension may not provide adequate spatial accommodation for proper subject fitment, while over-sized furnace may require higher degree of energy consumption, which leads to lower energy efficiency or lower yield rate of the product. However, as semiconductor devices come in all kind of sizes and shapes, it is generally uneconomical to employ a furnace with a fixed dimension that is solely tailored/optimized to process a target subject having a specific dimension.

In addition, conventional diffusion furnaces usually incorporate a plurality of internally affixed heating elements. Specifically, conventional heating elements generally consist of heating wires recessively arranged in the ceramic insulating layer of the furnace. However, these heating elements, especially the fixing joints thereof, may deform due to thermal expansion, which can cause premature failures and misplacements of the heating elements. Moreover, as portions of the heating elements in the furnace suffer damage after long-term usage, the internally affixed heating elements in the conventional non-modular furnaces usually makes inspection and repair unnecessarily difficult.

To address the above issues, the inventors strive via industrial experience and academic research to present the instant disclosure, which can effectively improve the limitations described above.

### SUMMARY OF THE INVENTION

One aspect of the instant disclosure provides a diffusion furnace that utilizes modularized design. It can be customized to satisfy different measurements requirement and can be easily decomposed for repair. Further, without the premature failure due to thermal expansion, the heating element of the diffusion furnace can be firmly secured.

Another aspect of the instant disclosure provides a diffusion furnace formed by a plurality of heating block units that incorporate externally affixed heating elements that can alleviate the adverse effects of thermal damage on the fixing/mounting joints thereof.

The diffusion furnace of the instant disclosure offers the following advantages. The diffusion furnace is modularized thus can be easily decomposed into several components such as heating panels, and each of the heating panels can also be easily dissembled into several heating blocks. As a result, it is convenient for the manufacturer of the diffusion furnace to customize every single diffusion furnace to satisfy the requirements of different customers. Furthermore, it is also convenient for the repairing of the diffusion furnace, for each modular component of the furnace can be easily dissembled and replaced.

In order to further appreciate the characteristics and technical contents of the instant disclosure, references are hereunder made to the detailed descriptions and appended drawings in connection with the instant disclosure. However, the appended drawings are merely shown for exemplary purposes, rather than being used to restrict the scope of the instant disclosure.

### BRIEF DESCRIPTION OF THE DRAWINGS

FIG. 1 is an assembled diagram of the diffusion furnace in accordance with an embodiment of the instant disclosure.

FIG. 2 is a partial exploded diagram of the diffusion furnace in accordance with the instant embodiment.

FIG. 3 is a partially exploded diagram of the heating panel in accordance with the instant embodiment.

FIG. 4 is an exploded diagram of the heating block in accordance with the instant embodiment.

FIG. 5 is another exploded diagram of the heating block in accordance with the instant embodiment.

FIG. 6 is a magnify diagram of the infrared heating element in accordance with the instant embodiment.

FIG. 7 is a cross-section diagram of the heating block in accordance with the instant embodiment.

FIG. 8 is an isometric view of an exemplary embodiment of a diffusion furnace in accordance with the instant disclosure in operational configuration.

FIG. 9 is a longitudinal cross-sectional view of the exemplary diffusion furnace as shown in FIG. 8.

### DETAILED DESCRIPTION OF PREFERRED EMBODIMENTS

The aforementioned illustrations and detailed descriptions are exemplarities for the purpose of further explaining the scope of the instant disclosure. Other objectives and advantages related to the instant disclosure will be illustrated in the subsequent descriptions and appended diagrams.

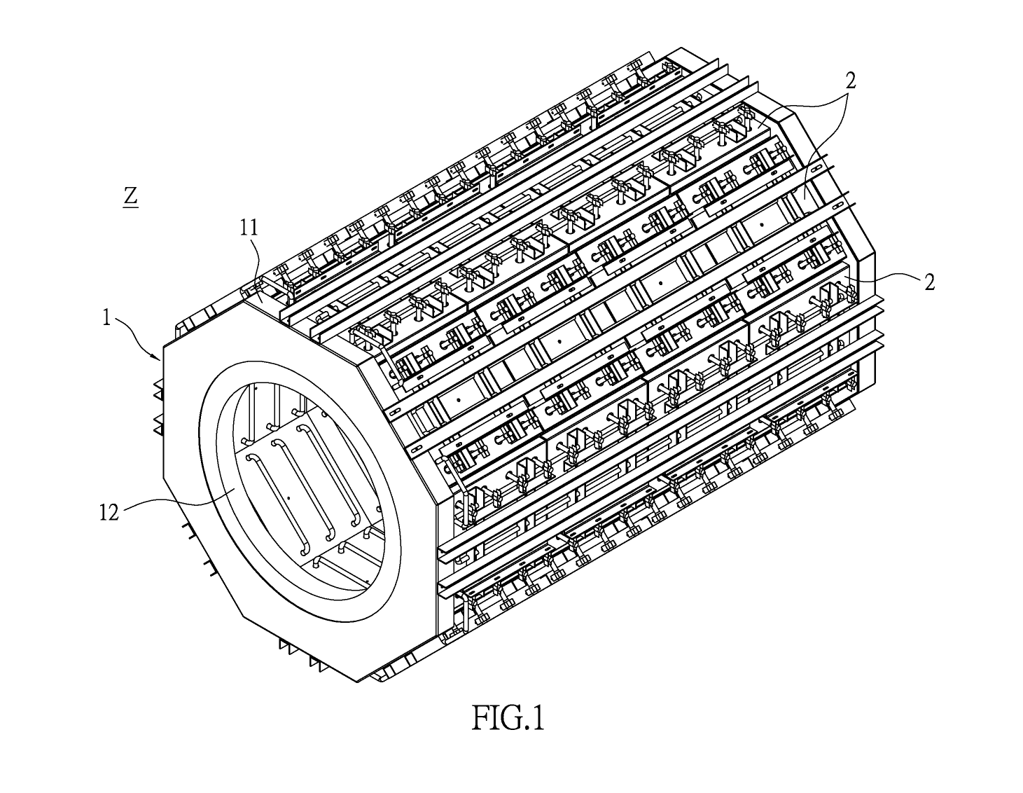

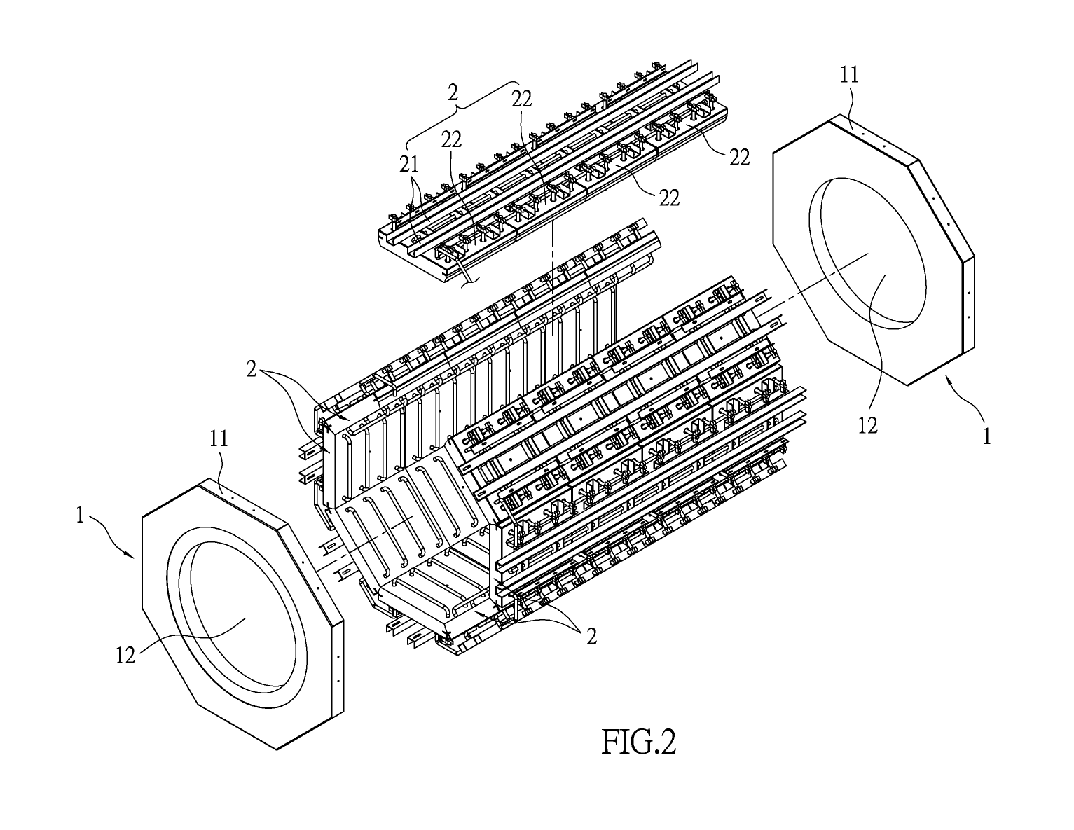

Refer to FIG. 1 and FIG. 2, which respectively show an isometric view of a diffusion furnace in accordance with an embodiment of the instant disclosure and a partial exploded diagram of the diffusion furnace as shown in FIG. 1. The diffusion furnace Z in accordance with the instant disclosure features modularized design, which offers exceptional convenience in the disassembly and repair of the equipment. The diffusion furnace Z can be used for the manufacturing of CIGS solar cell and other diffusion processes.

The diffusion furnace Z comprises two end frame plates 1 and a plurality of abreast-arranged heating panels 2, each of which transversely connecting the two end frame plates 1 as well as respectively connecting one another in an circumferentially enclosing manner, thus forming the diffusion furnace Z that defines an inner receiving compartment. As shown by FIG. 1, the diffusion furnace Z of the instant embodiment has an overall shape that resembles an octagonal prism, with the two end frame plates 1 arranged at opposite ends of the diffusion furnace Z in a substantially parallel configuration. The shape of the end frame plate 1 is preferably of n-sided right polygonal configuration in order to achieve higher degree of modular assemble-ability. For instance, the furnace Z of the instant embodiment, as shown in FIGS. 1 and 2, utilizes an octagonal end frame plate 1 to host eight sets of transversely-arranged elongated heating panels 2 there-between. Specifically, each respective end of the heating panel 2 is configured to structurally connect one of the eight sides of the octagonal end frame plate 1. Furthermore, in order to achieve better heating/energy efficiency, each pair of adjacent heating panels 2 may be tightly arranged or even structurally joined, thus cooperatively forming an enclosed hollow furnace body for housing variety of objects to be processed. In this case, the length of each of the sides of the polygonal end frame plate 1 is configured to be substantially equal to the width of the heating panel 2.

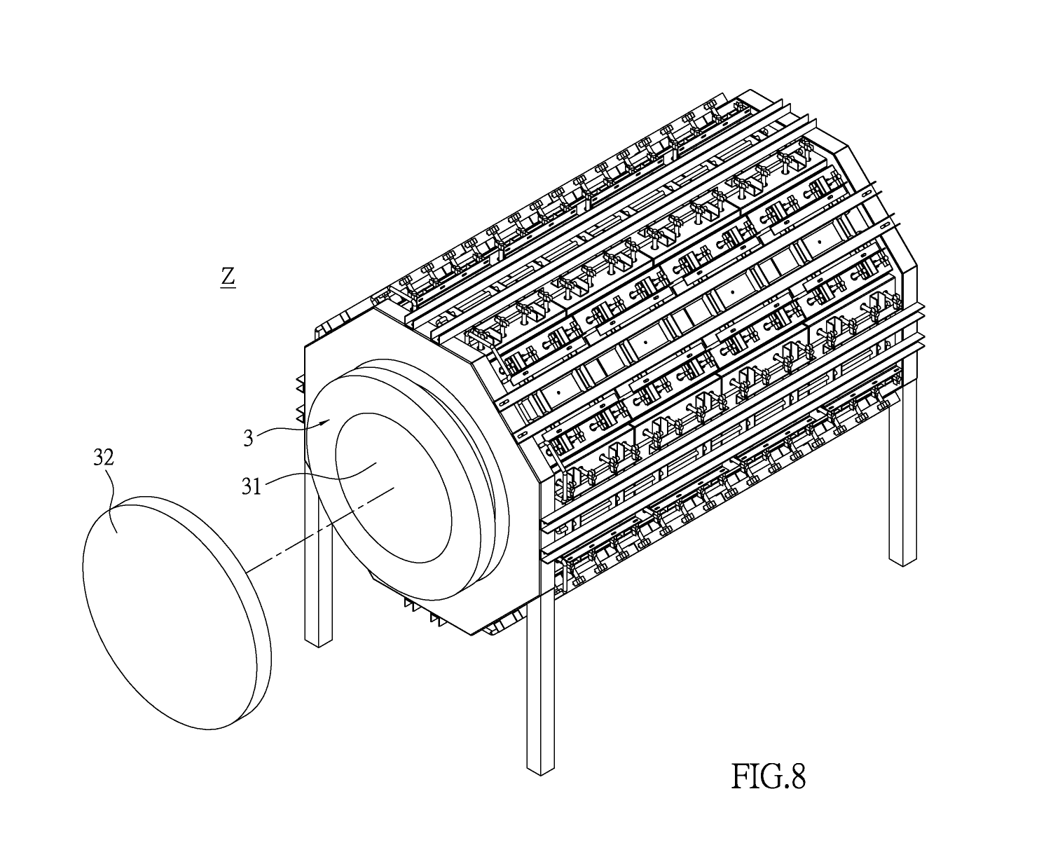

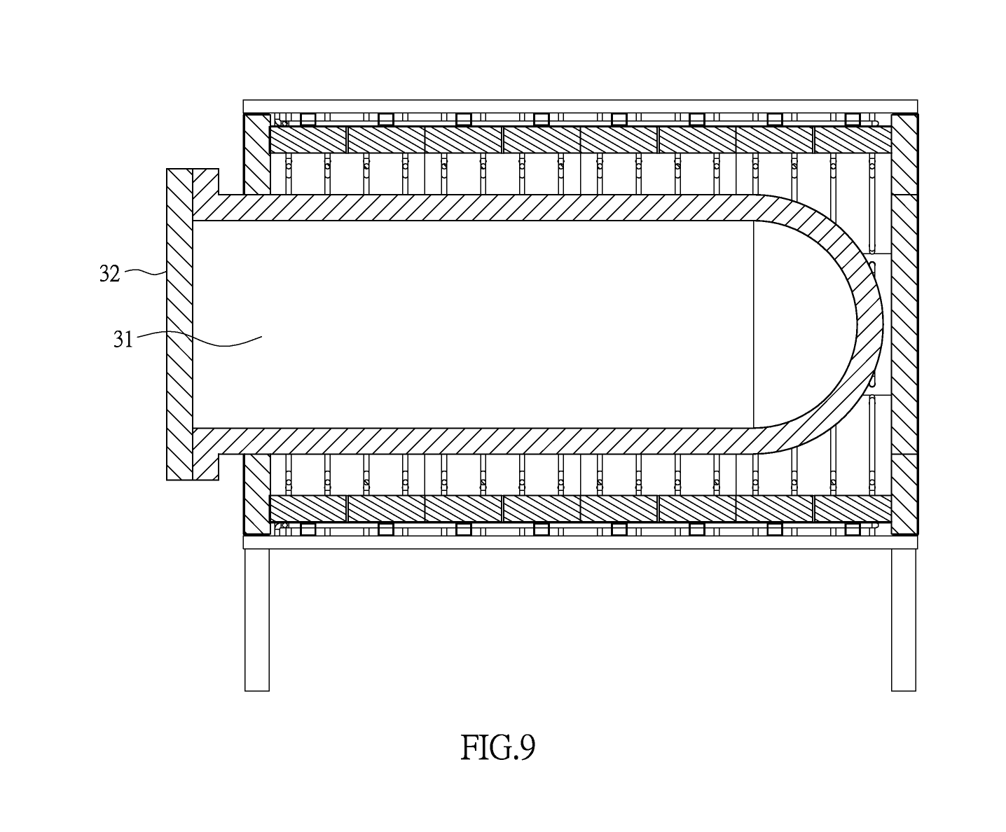

Please note that, end frame plates of different shapes/sizes may be used to take full advantage of the present invention's modular design. By way of example, right polygonal end frame plates that have different number of sides may be used with a corresponding number of heating panels to create a furnace of different size, thus providing higher degree of operational flexibility to accommodate target objects of various sizes and shapes. For example, an end frame plate with a higher number of sides may be adapted to create a furnace of larger internal volume to accommodate larger objects, while an end frame plate with a lower number of sides may be used to build a smaller furnace suitable for accommodating smaller objects. The number of sides on the end frame plate may be chosen to suit a particular operational requirement, and thus should not be limited to the exemplary configuration illustrated in the instant embodiment. One (or both) of the end frame plate 1 may be configured to incorporate an opening 12 to allow access to the internal volume of the furnace. In practical operation, the opening 12 on the end frame plate 1 is usually configured to allow insertion of an inner heating chamber 3 into the hollow body of the furnace Z, as shown in FIGS. 8 and 9. Generally, the inner heating chamber 3 is a hollow enclosure that has at least one opening 31 for allowing access to and from the receiving space defined therein. A cover 32 is preferably provided to create adequate sealing around the opening 31 during heating process. The selection of end frame plates of different dimensions gives the exemplary furnace the flexibility to accommodate inner heating chamber of various sizes and shapes, thereby increasing the operation adaptability of the diffusion furnace.

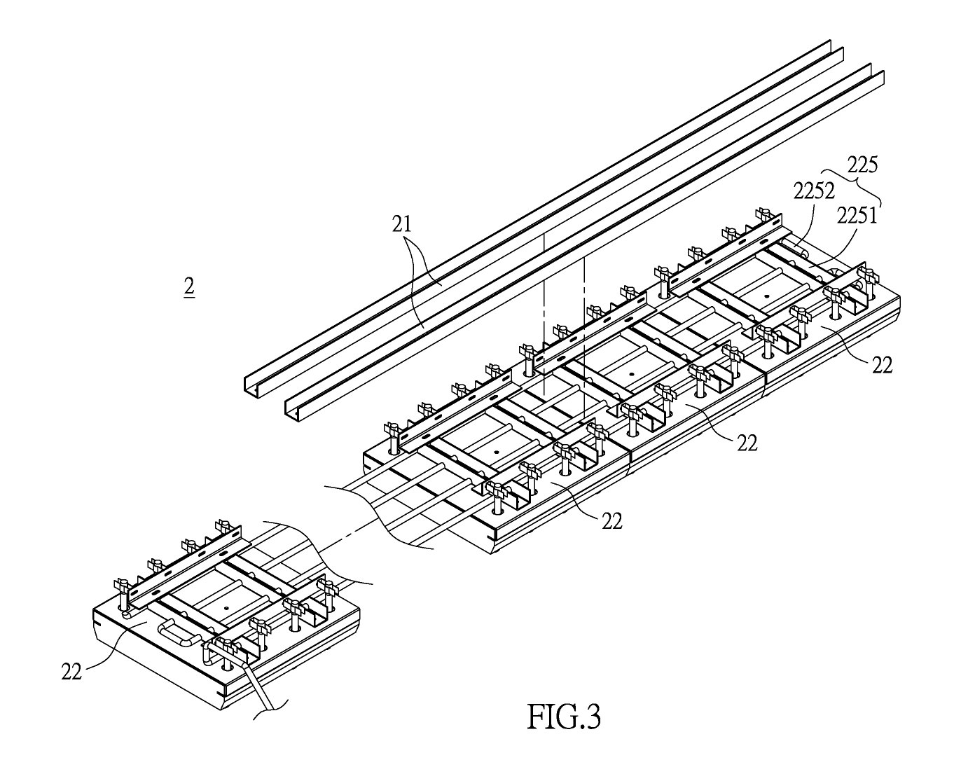

Please refer to FIG. 2 and FIG. 3. FIG. 3 shows a partially exploded diagram of the modular heating panel 2 in accordance with the instant disclosure. The heating panel 2 comprises a plurality of modular heating blocks 22 and at least one interjoining member 21 configured to structurally connecting the plurality of heating blocks. For structural simplicity, each heating panel 2 of the instant exemplary embodiment employs four modular heating blocks 22, each having an external shape that substantially resembles a square plate, and a pair of abreast-arranged beams 21 as interjoining members to tightly connect the four heating blocks 22 in a substantially linear succession manner, thus forming an elongated, rectangular panel module. In order to achieve better heating efficiency, it is preferable to establish tight fitment between each pair of neighboring heating blocks, thereby creating better thermal isolation. The connection between the beam 21 and each respective heating block 22 may be accomplished through suitable means, and can be either temporary or permanent. For example, for simplicity and reduced cost, permanent fixation techniques such as spot welding may be employed; for operational flexibility and maintainability, releasable retaining arrangements such as bolts and nuts (or other suitable interjoining/latching mechanisms) may be used to enable easy disassembly of the panel module.

Operationally, the amount of the heating blocks 22 and the beams 21 is determined by the dimension of the target object to be processed, such as the physical dimension of the thin-film solar cell. For instance, when a manufacturing process for a larger solar cell is required, a bigger diffusion furnace may be formed by selecting a pair of end frame plates that have more sides, as well as adapting heating panels that comprises higher numbers of heating blocks. Moreover, the diffusion furnace Z of the instant disclosure may be placed horizontally or vertically depends on the requirement of the heating process.

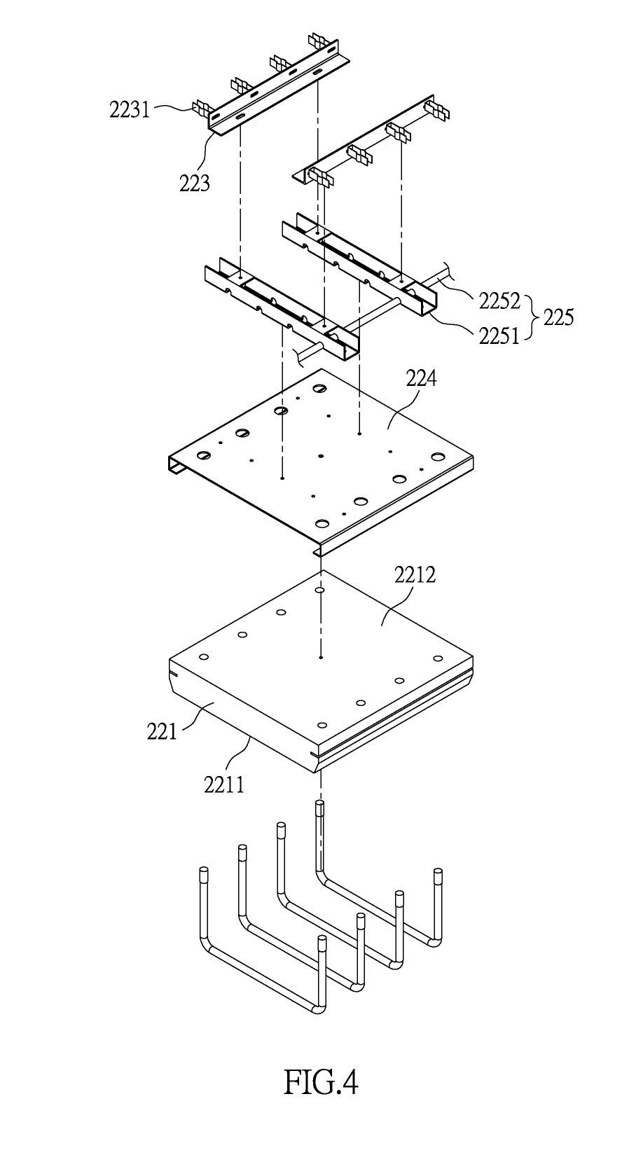

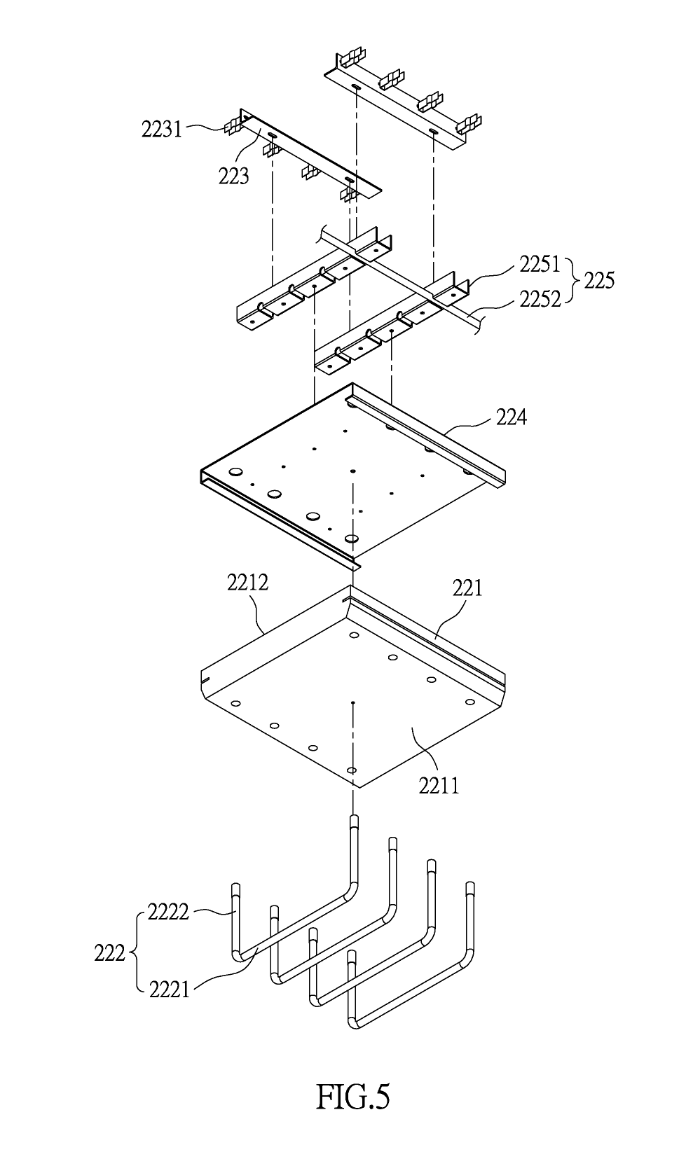

Please refer to FIGS. 3, 4, and 5. FIG. 4 is an isometric exploded diagram of an exemplary heating block in accordance with the instant embodiment, with focus on the outer-facing side thereof, while FIG. 5 is another isometric exploded diagram of the heating block in accordance with the instant embodiment, with focus on the inner-facing side. Each heating block 22, which serves as the fundamental modular unit for the instant diffusion furnace, comprises a block body 221 having a substantially planar profile, a cooling assembly 225 immediately arranged on an outer-facing surface of the block body 221, an externally arranged mounting assembly 223 (i.e., arranged on the outward-facing side of the block body), and at least one penetratively-arranged and outwardly affixed heating element 222. Specifically, the heating element 222 is configured to be penetratively inserted from one side (e.g., the designated inner-facing side) of the block body 221 and secured by the mounting assembly 223 on the other side (e.g., the designated outer-facing side) thereof. Such an externally affixing configuration allows the fixing joint between the heating element 222 and the mounting assembly 223 to stay outside the scorching heating chamber of the furnace Z. Accordingly, the incorporation of the externally affixed heating elements may effectively alleviate the adverse effects of thermal damage on the fixing/mounting joints thereof, thereby increasing the operational reliability and prolonging the life of the device.

The block body 221 is made by refractory material such as ceramic fiber or silicon carbide, and in this embodiment, has a shape that substantially resembles a square tile. The block body 221 has an inner surface 2211 designated to be arranged facing the inside of the diffusion furnace Z and an outer surface 2212 on the opposing side. The interjoining member (e.g., the beam 21) is configured to retain the block body 221 from the outer surface 2212, so that a plurality of the block bodies 221 can be positioned in line along the extending direction of the beam 21. It should be noted that, interjoining member of other configuration may also be adaptable to interconnect each pair of heating blocks 22 in order to form an elongated heating panel. For instance, instead of a long beam-like cross member (such as the one shown in the instant embodiment), a series of shorter interjoining members may be used between each pair of adjacent heating blocks to achieve similar purpose.

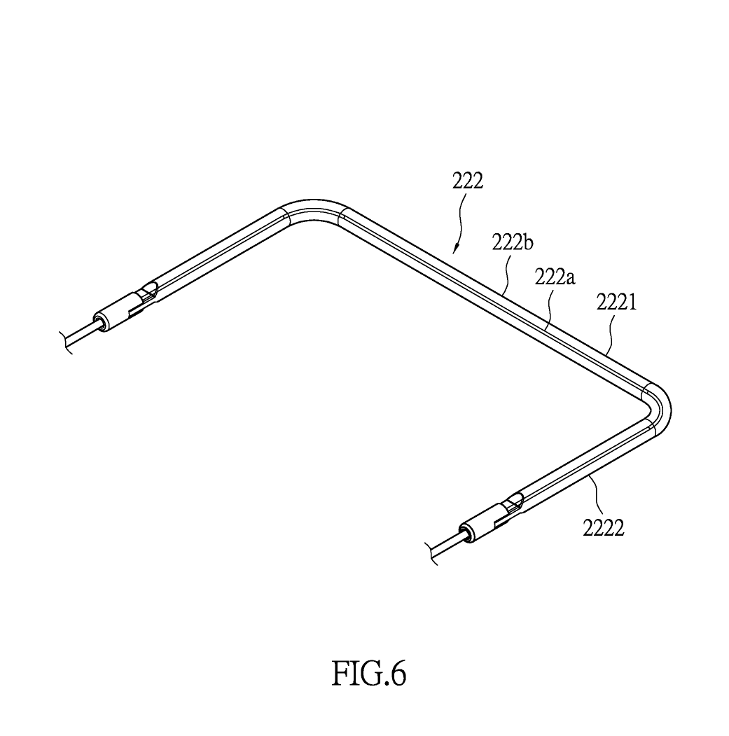

Please refer to FIG. 4 and FIG. 6, FIG. 6 is an enlarged view of the infrared heating element 222 in accordance with the instant embodiment. The infrared heating element 222 may be a generally elongated tubular heating wire that includes a refractory filament 222a (such as tungsten wire) protected within a quartz tube 222b, and comprises a central heating segment 2221 and a pair of fixing segments 2222 at opposite ends of the heating segment 2221. The exemplary heating element 222 of the instant embodiment is substantially U-shaped with the heating segment 2221 arranged in the valley portion and the pair of fixing segments 2222 forming the two arms of the letter “U.” The heating element 222 is configured to be penetratively arranged through the block body 222 from the inner surface 2211 thereof and retained externally on the other side (i.e., on the external side 2212). Accordingly, the block body 222 comprises a plurality of correspondingly displaced through holes to accommodate the insertion of the “arms” of the heating elements 222 there-through. Each heating block 22 of the instant embodiment incorporates four heating elements 222 that are squarely arranged in an aligning manner, with their respective heating segments 2221 substantially parallel to each other. However, it should be realized that the actual number and the specific placement of heating element may be flexibly chosen in accordance to practical operational requirements, and should not be limited to that illustrated in the figures and the description of the present embodiment.

The mounting assembly 223 is disposed externally on the block body 221 (on the side of the outer surface 2212) for securing the heating element 222. In the instant embodiment, the mounting assembly 223 comprises a pair of elongated mounting brackets (as shown in FIGS. 4 and 5) that are disposed on the cooling assembly 2251 and arranged substantially parallel to each other. Each mounting bracket includes four retaining member 2231 configured to respectively establish retaining connection with the fixing segment 2222 of the heating element 222. Specifically, upon the insertion of the heating element 222 through the mounting holes of the block body 221, the terminal portions of the fixing segments 2222 protrude from the outer side (i.e., on the side of the outer surface 2212) of the block body 221, forming two rows of protruding tips on the outer side of the heating block 22. Correspondingly, the retaining members 2231 of the mounting assembly 223, which are configured as retaining clamps in the instant embodiment, are designed to securely grab onto the protruding portion of the fixing segment 2222, thus forming an external mounting joint between the heating element 222 and the mounting assembly 223. Thus, the mounting joints between the heating member 222 and the mounting assembly 223 can be isolated from the heat inside of the diffusion furnace Z, thus preventing premature failures and misplacements of fixing segments 2222 and mounting assembly 223 caused by thermal expansion.

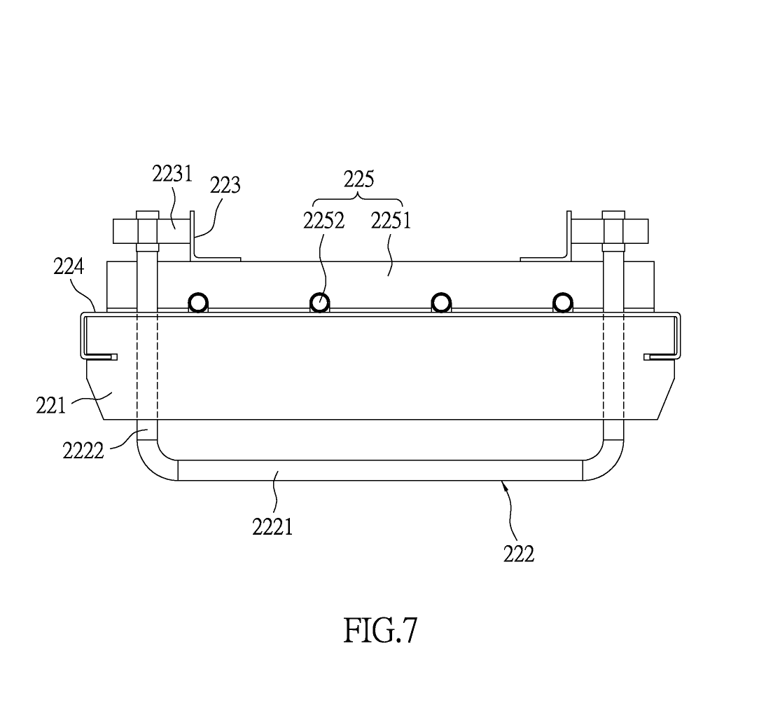

Please refer to FIG. 4 and FIG. 7. FIG. 7 is a cross-section diagram of the heating block in accordance with the instant embodiment, taken between a pair of adjacent heating elements 222 in a direction that is substantially parallel thereto. The heating block 22 may further comprise a reinforcing sheet 224 coveringly disposed on the outer surface 2212 of the block body 221 for providing additional structural strength. The reinforcing sheet 224 can be made by high strength material, such as stainless steel. The cross-sectional diagram also provides a clearer view of the cooling assembly 225, which is arranged in immediate contact with the outer surface of the block body 221 (e.g., the reinforcing sheet 224 of the instant embodiment). The cooling assembly 225 may include at least one holding bar 2251 mounted on the reinforcing sheet 224 and at least one cooling pipe 2252 arranged in thermal contact with the outer surface of the block body 221 to provide more direct and effective cooling capacity. By way of example, to increase cooling efficiency yet maintain structural simplicity, the exemplary heating panel 2 of instant embodiment employs a cooling pipe 2252 having multiple bent sections (in this case, four bent sections arranged substantially parallel to each other), with each bent section thereof running substantially across the length of the heating panel 2 (as better illustrated in FIG. 3). Moreover, the mounting assembly 223 may be mounted directly on (or at least in thermal contact with) the cooling assembly 225, as illustrated by the instant embodiment, to further increase the cooling efficiency of the diffusion furnace. Therefore, when residual heat is transmitted from the inner surface 2211 of the block body 221 to the outer surface 2212, it can be absorbed by the reinforcing sheet 224 (which is cooled by the cooling pipe 2252), thus reducing the heat transmitted to the protruded portion of the fixing segment 2222.

The diffusion furnace of the instant disclosure has the following advantages. The diffusion furnace is modularized thus can be easily dissembled into several components such as heating panels, and each of the heating panels can also be easily decomposed into several heating blocks. As a result, it is convenient for the manufacturer of the diffusion furnace to customize every single diffusion furnace to satisfy the requirements of different customers. Furthermore, it is also convenient for the repairing of the diffusion furnace, for each component of the furnace can be easily dissembled and replaced.

The descriptions illustrated supra set forth simply the preferred embodiment of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. A diffusion furnace, comprising:
a pair of end frame plates (1), each having a substantially n-sided right polygonal profile, arranged substantially in parallel and defining the opposing end walls of the furnace, wherein n is a positive integer; and
at least n modular heating panels (2) respectively connected between the two end frame plates in a circumferentially enclosing manner to define the lateral side walls of the furnace;
wherein each heating panel (2) comprises:
a plurality of modular heating blocks (22), and
at least one interjoining member (21) adapted to structurally connect the plurality of heating blocks in a substantially linear succession manner;
wherein each heating block (22) comprises:
a block body (221) designating an inner surface (2211) and an opposing outer surface (2212),
at least one heating element (222) including a centrally arranged heating segment (2221) and a pair of fixing segments (2222) respectively arranged at the two opposite sides thereof, the heating element configured to be penetratively disposed through the block body (224) from the inner surface thereof with a portion of each fixing segment respectively protruding from the outer surface, and
a mounting assembly (223) disposed on the outer side of the block body configured to establish external fixing connection with the protruding portion of the fixing segment of the heating element.

2. The diffusion furnace of claim 1, wherein the heating block further comprises a reinforcing sheet coveringly disposed on the outer side of the block body to define an outer surface thereof.

3. The diffusion furnace of claim 2, further comprising a cooling assembly (225) immediately disposed on the outer surface of the block body (221).

4. The diffusion furnace of claim 3, wherein the cooling assembly includes at least one holding bar (2251) mounted on the outer surface of the block body and at least one cooling pipe retained by the holding bar and arranged in thermal contact with the reinforcing sheet.

5. The heating block of claim 1, wherein the mounting assembly comprises at least one retaining member (2231) having a pair of free ends configured to cooperatively clamp onto the protruding portion of the fixing segment of the heating element.

6. A modular heating panel (2) of a diffusion furnace (Z), comprising:
a plurality of modular heating blocks (22); and
at least one interjoining member (21) adapted to structurally connect the plurality of heating blocks in a substantially linear succession manner, wherein each heating block (22) comprises:
a block body (221) designating an inner surface (2211) and an opposing outer surface (2212);
at least one heating element (222) including a centrally arranged heating segment (2221) and a pair of fixing segments (2222) respectively arranged at the two opposite sides thereof, the heating element configured to be penetratively disposed through the block body (224) from the inner surface thereof with a portion of each fixing segment respectively protruding from the outer surface; and
a mounting assembly (223) disposed on the outer side of the block body configured to establish external fixing connection with the protruding portion of the fixing segment of the heating element.

7. The heating panel of claim 6, wherein the heating block further comprises a reinforcing sheet (224) coveringly disposed on the outer side of the block body to define an outer surface thereof.

8. The heating panel of claim 7, further comprising a cooling assembly (225) immediately disposed on the outer surface of the block body (221).

9. The heating panel of claim 8, wherein the cooling assembly includes at least one holding bar (2251) mounted on the outer surface of the block body and at least one cooling pipe retained by the holding bar and arranged in thermal contact with the reinforcing sheet.

10. The heating block of claim 6, wherein the mounting assembly comprises at least one retaining member (2231) having a pair of free ends configured to cooperatively clamp onto the protruding portion of the fixing segment of the heating element.

11. A heating block (22) for a modular heating panel (2) of a diffusion furnace (Z), comprising:
a block body (221) designating an inner surface (2211) and an opposing outer surface (2212);
at least one heating element (222) including a centrally arranged heating segment (2221) and a pair of fixing segments (2222) respectively arranged at the two opposite sides thereof, the heating element configured to be penetratively disposed through the block body (224) from the inner surface thereof with a portion of each fixing segment respectively protruding from the outer surface; and
a mounting assembly (223) disposed on the outer side of the block body configured to establish external fixing connection with the protruding portion of the fixing segment of the heating element.

12. The heating block of claim 11, wherein the heating block further comprises a reinforcing sheet (224) coveringly disposed on the outer side of the block body to define an outer surface thereof.

13. The heating block of claim 12, further comprising a cooling assembly (225) immediately disposed on the outer surface of the block body (221).

14. The heating block of claim 13, wherein the cooling assembly includes at least one holding bar (2251) mounted on the outer surface of the block body and at least one cooling pipe retained by the holding bar and arranged in thermal contact with the reinforcing sheet.

15. The heating block of claim 11, wherein the mounting assembly comprises at least one retaining member (2231) having a pair of free ends configured to cooperatively clamp onto the protruding portion of the fixing segment of the heating element.
